(19) United States
(12) Patent Application Publication
(10) Pub. No.: US 2005/0173096 A1
(43) Pub. Date: Aug. 11, 2005

(54) Heat dissipating device

(75) Inventors: Shih-Ying Hsu, Taipei City (TW); Chung-Ter Yang, Hsinchu (TW)

Correspondence Address: OSTROLENK FABER GERB & SOFFEN, 1180 AVENUE OF THE AMERICAS, NEW YORK, NY, 100368403, US

(73) Assignee: Wincomm Corporation

(21) Appl. No.: 10/874,434

(22) Filed: Jun. 22, 2004

(30) Foreign Application Priority Data
Feb. 5, 2004 (TW) 093102657

(51) Int. Cl. F28D 15/00; H05K 7/20

(52) U.S. Cl. 165/104.21

(57) ABSTRACT

A heat dissipating device includes a fluid container made of a heat conductive material and having a heat-dissipating wall opposite to a heat-absorbing wall, and a surrounding wall cooperating with the heat-absorbing and heat-dissipating walls so as to confine a sealed vapor chamber. A heat exchanger member is disposed in the vapor chamber, is in heat-conductive contact with the heat-absorbing wall, and contains an amount of working fluid capable of changing into fluid vapor that fills the vapor chamber upon absorbing heat from the heat-absorbing wall. The fluid vapor is capable of changing into fluid condensate when cooled due to contact with the heat-dissipating wall. A heat-conductive cover plate is mounted spacedly on the heat-dissipating wall of the fluid container, and cooperates with the heat-dissipating wall so as to confine a heat-dissipating passage therebetween such that heat absorbed by the heat-dissipating wall is dissipated via the heat-dissipating passage.

### CROSS-REFERENCE TO RELATED APPLICATION

This application claims priority of Taiwanese Application No. 093102657, filed on Feb. 5, 2004.

### BACKGROUND OF THE INVENTION

1. Field of the Invention

The invention relates to a heat dissipating device, more particularly to a heat dissipating device having a relatively high heat dissipating efficiency.

2. Description of the Related Art

FIG. 1 illustrates a conventional heat dissipating device for dissipating heat generated by a CPU 10. The conventional heat-dissipating device includes a heat transfer plate 11 having a first surface 111 placed in heat conductive contact with the CPU 10, and a second surface 110 opposite to the first surface, a heat exchanger pipe 12 having a first end portion 120 that is connected to the second surface 110 of the heat transfer plate 11, and a second end portion 121 opposite to the first end portion 120, a heat sink 14 coupled to the second end potion 121 of the heat exchanger pipe 12, and a fan unit 15 that includes a fan housing 152 with an air inlet 154 and an air outlet 153. The heat sink 14 is disposed in the fan housing 152 at the air outlet 153.

Due to the use of the fan unit 15, noise occurs during high-speed rotation. In addition, dust accumulated in the fan housing 152 hampers the heat-dissipating efficiency of the conventional heat dissipating device.

### SUMMARY OF THE INVENTION

Therefore, the object of the present invention is to provide a heat dissipating device that has a relatively high heat dissipating efficiency.

According to the present invention, a heat dissipating device comprises:
a fluid container made of a heat conductive material and having a heat-absorbing wall, a heat-dissipating wall opposite to the heat-absorbing wall, and a surrounding wall cooperating with the heat-absorbing and heat-dissipating walls so as to confine a sealed vapor chamber;
a heat exchanger member disposed in the vapor chamber, the heat exchanger member being in heat-conductive contact with the heat-absorbing wall and containing an amount of working fluid, the working fluid being capable of changing into fluid vapor that fills the vapor chamber when absorbing heat from the heat-absorbing wall, the fluid vapor being capable of changing into fluid condensate when cooled due to contact with the heat-dissipating wall; and
a heat-conductive cover plate mounted spacedly on the heat-dissipating wall of the fluid container and cooperating with the heat-dissipating wall so as to confine a heat-dissipating passage therebetween such that heat absorbed by the heat-dissipating wall is dissipated via the heat-dissipating passage.

### BRIEF DESCRIPTION OF THE DRAWINGS

Other features and advantages of the present invention will become apparent in the following detailed description of the preferred embodiments with reference to the accompanying drawings, of which:

FIG. 1 is a perspective view of a conventional heat dissipating device;

FIG. 2 is an exploded perspective view showing the first preferred embodiment of a heat dissipating device according to the present invention;

FIG. 3 is a fragmentary schematic sectional view showing the first preferred embodiment;

FIG. 4 is an enlarged view of a portion illustrated in FIG. 3;

FIG. 5 is an exploded perspective view showing the second preferred embodiment of a heat dissipating device according to the present invention;

FIG. 6 is a fragmentary schematic sectional view showing the third preferred embodiment of a heat dissipating device according to the present invention; and

FIG. 7 is a fragmentary schematic sectional view showing the fourth preferred embodiment of a heat dissipating device according to the present invention.

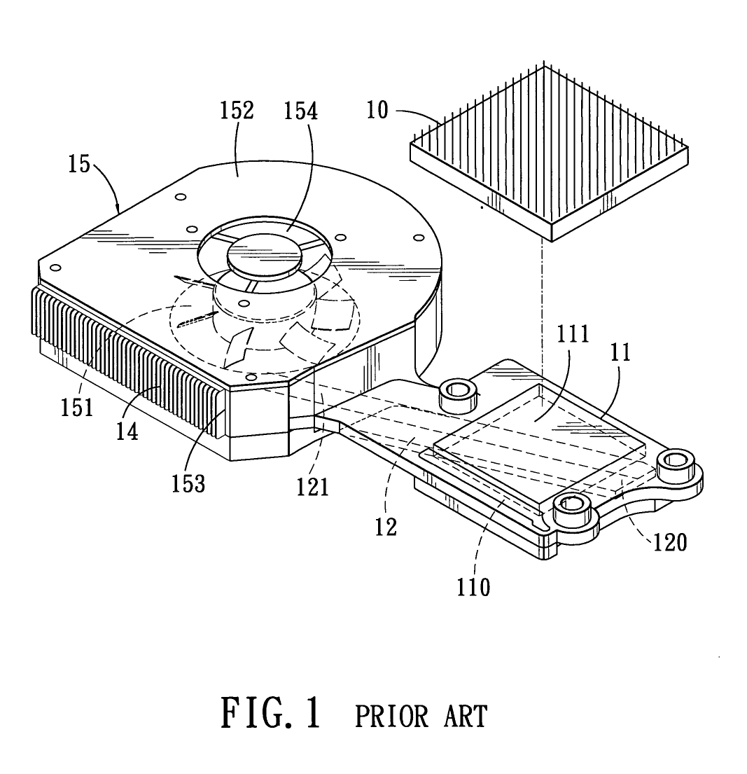

### DETAILED DESCRIPTION OF THE PREFERRED EMBODIMENTS

Before the present invention is described in greater detail, it should be noted that like elements are denoted by the same reference numerals throughout the disclosure.

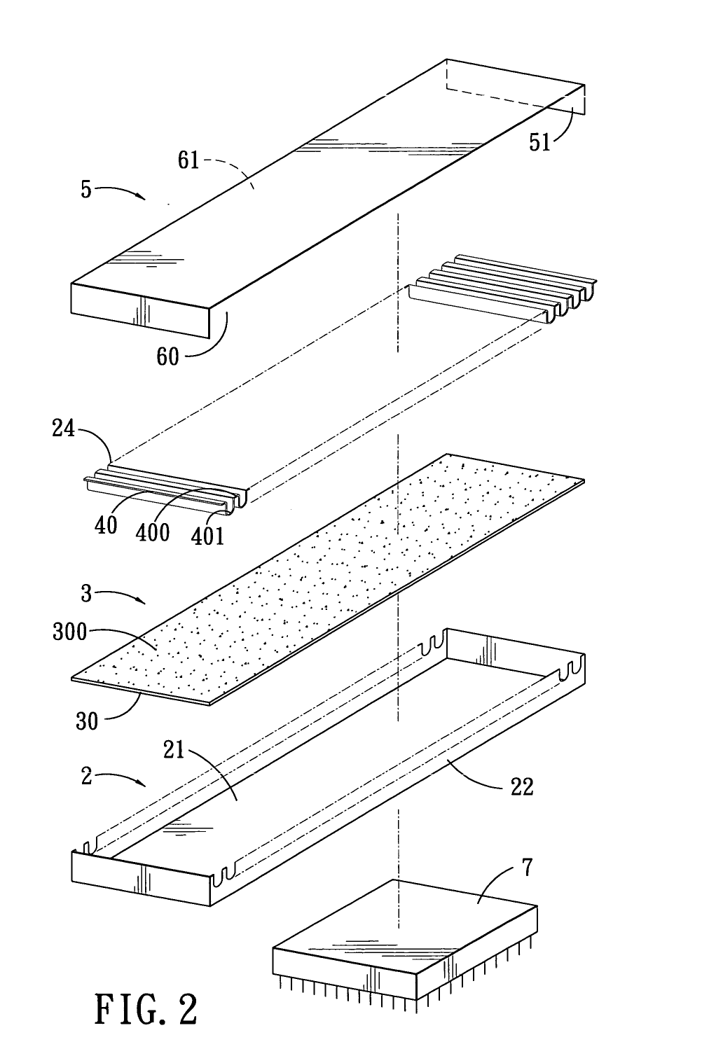

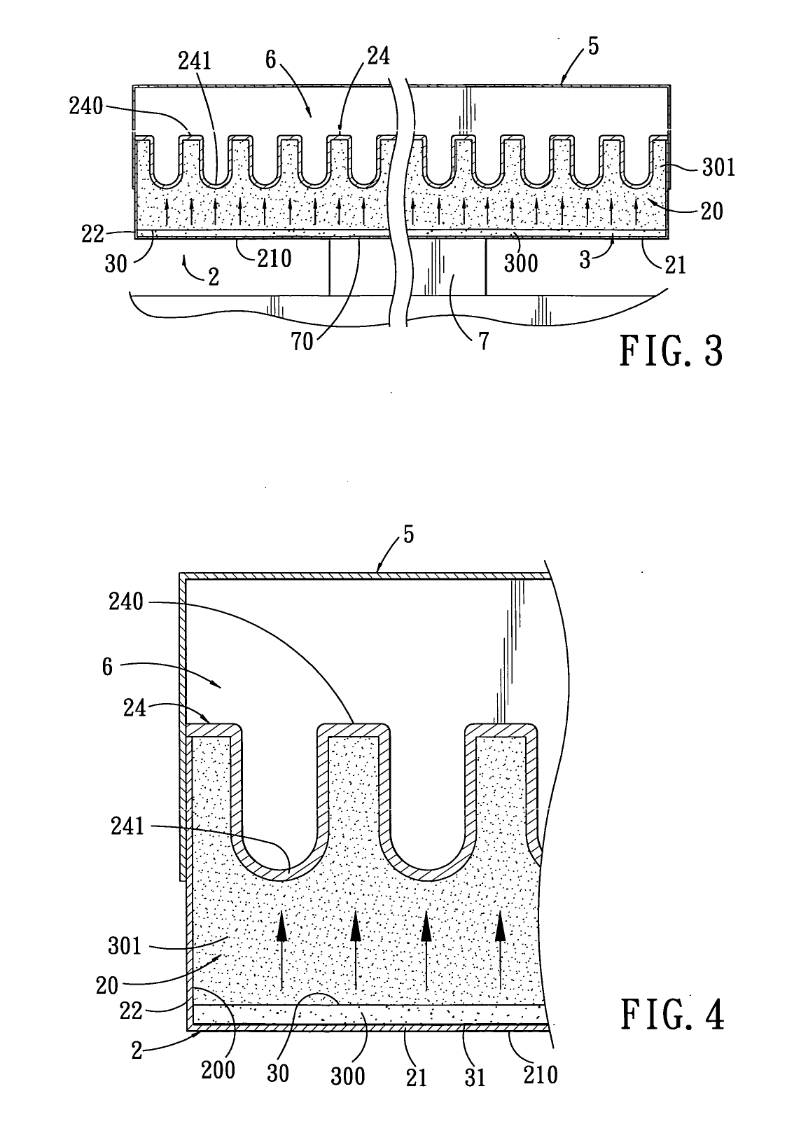

Referring to FIGS. 2 and 3, the first preferred embodiment of a heat dissipating device according to the present invention is shown to include a fluid container 2, a heat exchanger member 3, and a heat-conductive cover plate 5.

The fluid container 2 is made of a heat conductive material, such as copper, and has a heat-absorbing wall 21, a heat-dissipating wall 24 opposite to the heat-absorbing wall 21, and a surrounding wall 22 cooperating with the heat-absorbing and heat-dissipating walls 21, 24 so as to confine a sealed vapor chamber 20, which is preferaly a vacuum chamber, as best shown in FIG. 2. In this embodiment, the heat-absorbing wall 21 is adapted to be placed in heat-conductive contact with a heat source 7, such as a central processing unit. In this embodiment, the heat-dissipating wall 24 has an undulated configuration that includes flattened peaks 240 and rounded valleys 241.

The heat exchanger member 3, which is disposed in the vapor chamber 20, is in heat-conductive contact with the heat-absorbing wall 21, and contains an amount of working fluid 300. The working fluid 300 is capable of changing into fluid vapor 301 that fills the vapor chamber 20 when absorbing heat from the heat-absorbing wall 21, as best shown in FIG. 4. The fluid vapor 301 is capable of changing into fluid condensate when cooled due to contact with the heat-dissipating wall 24. In this embodiment, the heat exchanger member 3 includes a porous ceramic plate 30 that contains the working fluid 300. The working fluid 300 includes at least one of water and a coolant. It is noted that a heat conductive medium 31, such as a heat-conductive adhesive or solder, may be employed for mounting the heat exchanger member 3 on the heat-absorbing wall 21 of the fluid container 2, as shown in FIG. 4.

The heat-conductive cover plate 5 is mounted spacedly on the heat-dissipating wall 24 of the fluid container 2, and cooperates with the heat-dissipating wall 24 so as to confine a heat-dissipating passage 6 therebetween, as shown in FIG. 3, such that heat absorbed by the heal-dissipating wall 24 is dissipated via the heat-dissipating passage 6. In this embodiment, the cover plate 5 is inverted U-shaped to configure the heat-dissipating passage 6 with opposite open lateral sides 60, 61, as shown in FIG. 2.

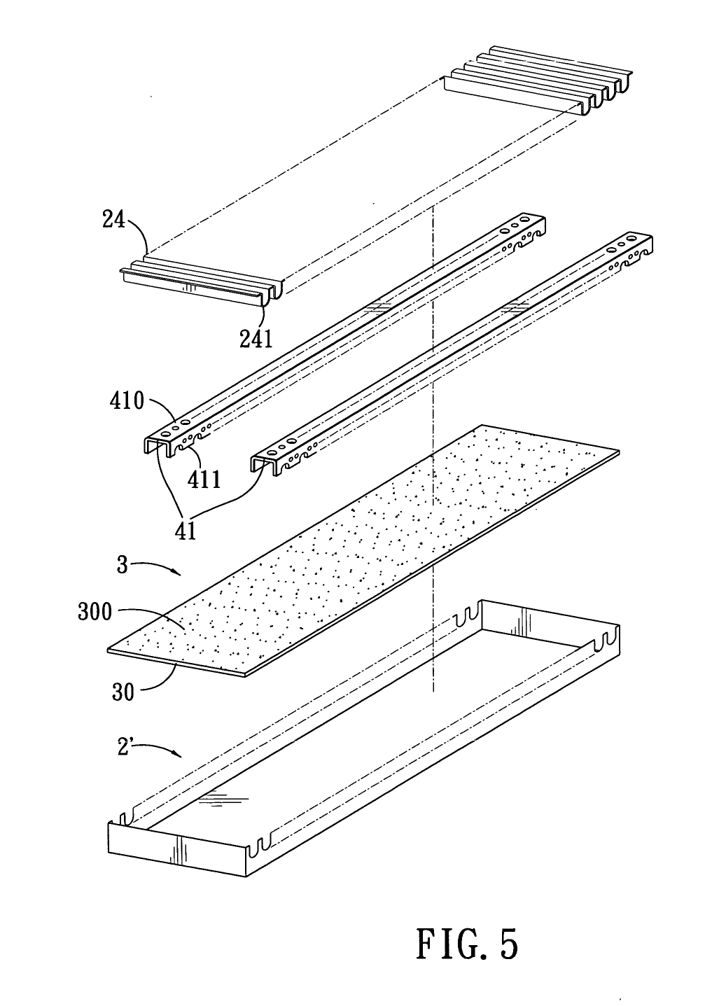

FIG. 5 illustrates the second preferred embodiment of a heat dissipating device according to this invention, which is a modification of the first preferred embodiment. In this embodiment, the fluid container 2′ further has a pair of elongate supporting frames 41 received in the vapor chamber and disposed between the heat-dissipating wall 24 and the heat exchanger member 3 for supporting the heat-dissipating wall 24. In this embodiment, each supporting frame 41 has a top side 410 abutting against the valleys 241 of the heat-dissipating wall 24, and a bottom side 411 abutting against the heat exchanger member 3.

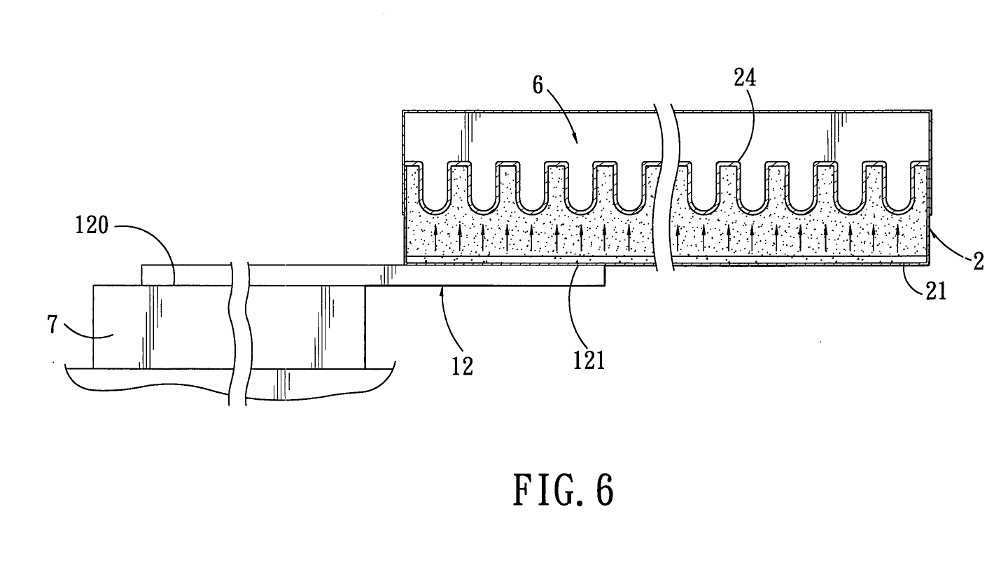

FIG. 6 illustrates the third preferred embodiment of a heat dissipating device according to this invention, which is a modification of the first preferred embodiment. In this embodiment, the heat dissipating device further includes a heat exchanger pipe 12 that has a device connecting side 120 adapted to be placed in contact with the heat source 7, and a wall connecting side 121 opposite to the device connecting side 120 and mounted on the heat-absorbing wall 21 of the fluid container 2.

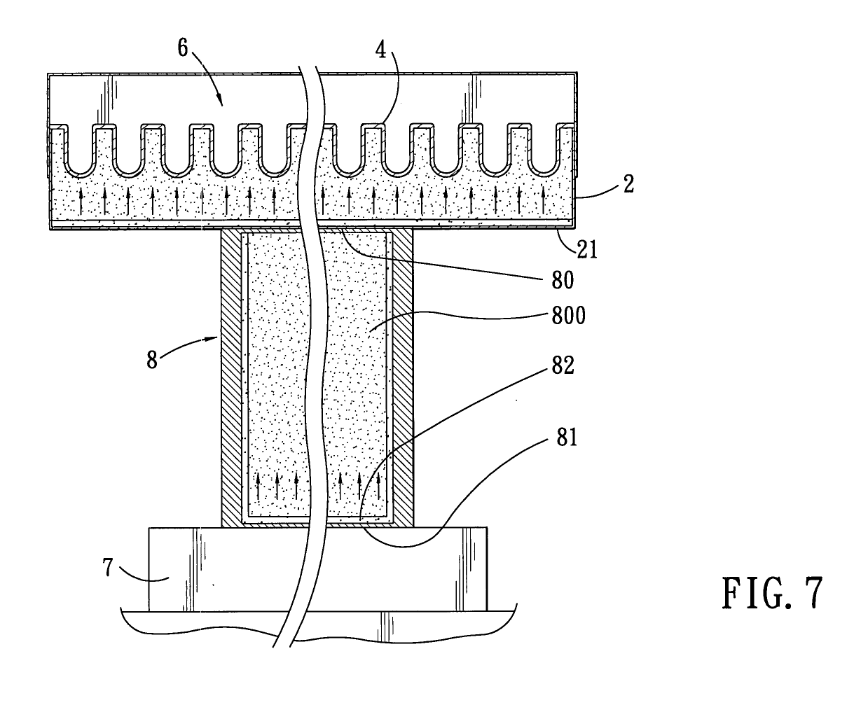

FIG. 7 illustrates the fourth preferred embodiment of a heat dissipating device according to this invention, which is a modification of the first preferred embodiment. In this embodiment, the heat dissipating device further includes a heat exchanger pipe 8 that has a lower device connecting side 81 adapted to be placed in contact with the heat source 7, and an upper wall connecting side 80 mounted on the heat-absorbing wall 21 of the fluid container 2. It is noted that the heat exchanger pipe 8 is configured with a vacuum space 800, and is provided with a porous ceramic tube 82 that contains a working fluid.

The following are some of the advantages of the heat dissipating device according to the present invention:

1. Due to the presence of the heat exchanger member 3 and the heat exchanger pipe 12, 8 with the working fluid, the heat dissipating device of this invention can provide a higher heat dissipating efficiency as compared to the prior art.

2. Due to the presence of the heat exchanger pipe 12, 8, the heat dissipating device of this invention can be suitable for heat sources disposed at different positions and having different sizes.

3. Noise resulting from the fan in the aforesaid conventional heat dissipating device can be avoided.

4. Due to the presence of the heat-dissipating passage 6, the heat dissipating device can achieve a chimney effect for enhancing the heat dissipating efficiency.

5. Due to the undulated configuration of the heat-dissipating wall 24, the heat dissipating device of this invention has a relatively large heat-dissipating area.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

1. A heat dissipating device comprising:
a fluid container made of a heat conductive material and having a heat-absorbing wall, a heat-dissipating wall opposite to said heat-absorbing wall, and a surrounding wall cooperating with said heat-absorbing and heat-dissipating walls so as to confine a sealed vapor chamber;
a heat exchanger member disposed in said vapor chamber, said heat exchanger member being in heat-conductive contact with said heat-absorbing wall and containing an amount of working fluid, said working fluid being capable of changing into fluid vapor that fills said vapor chamber when absorbing heat from said heat-absorbing wall, said fluid vapor being capable of changing into fluid condensate when cooled due to contact with said heat-dissipating wall; and
a heat-conductive cover plate mounted spacedly on said heat-dissipating wall of said fluid container and cooperating with said heat-dissipating wall so as to confine a heat-dissipating passage therebetween such that heat absorbed by said heat-dissipating wall is dissipated via said heat-dissipating passage.

2. The heat dissipating device as claimed in claim 1, wherein said heat-dissipating wall has an undulated configuration.

3. The heat dissipating device as claimed in claim 2, wherein the undulated configuration of said heat-dissipating wall includes flattened peaks and rounded valleys.

4. The heat dissipating device as claimed in claim 1, wherein said heat exchanger member includes a porous ceramic plate that contains said working fluid.

5. The heat dissipating device as claimed in claim 1, wherein said fluid container further has an elongate supporting frame received in said vapor chamber and disposed between said heat-dissipating wall and said heat exchanger member for supporting said heat-dissipating wall.

6. The heat dissipating device as claimed in claim 1, wherein said vapor chamber is a vacuum chamber.

7. The heat dissipating device as claimed in claim 1, wherein said working fluid includes at least one of water and a coolant.

8. The heat dissipating device as claimed in claim 1, further comprising a heat exchanger pipe that has a device connecting side adapted to be placed in contact with a heat source, and a wall connecting side opposite to said device connecting side and mounted on said heat-absorbing wall of said fluid container.

9. The heat dissipating device as claimed in claim 8, wherein said heat exchanger pipe is configured with a vacuum space, and is provided with a porous ceramic tube that contains a working fluid.

10. The heat dissipating device as claimed in claim 1, wherein said heat-dissipating passage has open lateral sides.

11. The heat dissipating device as claimed in claim 1, wherein said cover plate is inverted U-shaped to configure said heat-dissipating passage with open lateral sides.

12. The heat dissipating device as claimed in claim 1, further comprising a heat conductive medium for mounting said heat exchanger member on said heat-absorbing wall.
